(19) United States
(12) Patent Application Publication
(10) Pub. No.: US 2022/0376082 A1
(43) Pub. Date: Nov. 24, 2022

(54) SEMICONDUCTOR DEVICE AND FABRICATION METHOD THEREOF

(71) Applicant: INNOSCIENCE (SUZHOU) TECHNOLOGY CO., LTD., SUZHOU CITY (CN)

(72) Inventors: Anbang ZHANG, ZHUHAI CITY (CN); King Yuen WONG, ZHUHAI CITY (CN)

(21) Appl. No.: 17/257,291

(22) PCT Filed: Dec. 14, 2020
(86) PCT No.: PCT/CN2020/136044

§ 371 Date: Dec. 30, 2020

(51) Int. Cl. H01L 29/66; H01L 29/20; H01L 29/778

(52) U.S. Cl. CPC H01L 29/66462; H01L 29/2003; H01L 29/66545; H01L 29/7786

(57) ABSTRACT

The present disclosure provides a semiconductor device and a fabrication method thereof. The semiconductor device includes a first nitride semiconductor layer, a second nitride semiconductor layer, a gate structure, a first spacer and a second spacer. The second nitride semiconductor layer is formed on the first nitride semiconductor layer and having a greater bandgap than that of the first nitride semiconductor layer. The gate structure is disposed on the second nitride semiconductor layer. The first spacer is disposed on the second nitride semiconductor layer. The in second spacer is disposed on the second nitride semiconductor layer and spaced apart from the first spacer by the gate structure. The bottom of the first spacer has a first width, the bottom of the second spacer has a second width, and the first width is different from the second width.

### BACKGROUND

### 1. Technical Field

The present disclosure relates to a semiconductor device and a fabrication method thereof.

### 2. Description of the Related Art

Components including direct bandgap semiconductors, for example, semiconductor components including group III-V materials or group III-V compounds (Category: III-V compounds) can operate or work under a variety of conditions or in a variety of environments (e.g., at different voltages and frequencies) due to their characteristics.

The semiconductor components may include a heterojunction bipolar transistor (HBT), a heterojunction field effect transistor (HFET), a high-electron-mobility transistor (HEMT), a modulation-doped FET (MODFET) and the like.

### SUMMARY OF THE INVENTION

In some embodiments of the present disclosure, a semiconductor device is provided, which includes a first nitride semiconductor layer, a second nitride semiconductor layer, a gate structure, a first spacer and a second spacer. The second nitride semiconductor layer is formed on the first nitride semiconductor layer and having a greater bandgap than that of the first nitride semiconductor layer. The gate structure is disposed on the second nitride semiconductor layer. The first spacer is disposed on the second nitride semiconductor layer. The second spacer is disposed on the second nitride semiconductor layer and spaced apart from the first spacer by the gate structure. The bottom of the first spacer has a first width, the bottom of the second spacer has a second width, and the first width is different from the second width.

In some embodiments of the present disclosure, a semiconductor device is provided, which includes a first nitride semiconductor layer, a second nitride semiconductor layer, a first doped group III-V semiconductor layer and a second doped group III-V semiconductor layer. The first nitride semiconductor layer has a first surface. The second nitride semiconductor layer is formed on the first nitride semiconductor layer and having a greater bandgap than that of the first nitride semiconductor layer. The first doped group III-V semiconductor layer and the second doped group III-V semiconductor layer are formed on the first surface of the first nitride semiconductor layer and located on two lateral sides of the second nitride semiconductor layer.

In some embodiments of the present disclosure, a method for manufacturing a semiconductor device is provided. The method includes forming a first nitride semiconductor layer; and forming a second nitride semiconductor layer on a first surface of the first nitride semiconductor layer, the second nitride semiconductor layer having a greater bandgap than that of the first nitride semiconductor layer. The method also includes forming a gate structure on the second nitride semiconductor layer; and forming a passivation layer on the second nitride semiconductor layer and the gate structure. The method further includes anisotropically removing a portion of the passivation layer.

### BRIEF DESCRIPTION OF THE DRAWINGS

Aspects of the present disclosure are readily understood from the following detailed description when read with the accompanying figures. It should be noted that various features may not be drawn to scale. In fact, the dimensions of the various features may be arbitrarily increased or reduced for clarity of discussion.

FIG. 1 is a cross-sectional view of a semiconductor device according to some embodiments of the present disclosure;

FIG. 2A is a cross-sectional view of a semiconductor device according to some embodiments of the present disclosure;

FIG. 2B is a cross-sectional view of a semiconductor device according to some embodiments of the present disclosure;

FIG. 2C is a cross-sectional view of a semiconductor device according to some embodiments of the present disclosure;

FIGS. 3A, 3B, 3C, 3D, 3E, 3F, 3G, 3H, 3I, 3J, 3K, 3L, 3M, 3N and 3O illustrate several operations in manufacturing a semiconductor device according to some embodiments of the present disclosure;

FIGS. 4A, 4B and 4C illustrate several operations in manufacturing a semiconductor device according to some embodiments of the present disclosure;

FIGS. 5A and 5B illustrate several operations in manufacturing a semiconductor device according to some embodiments of the present disclosure; and

FIGS. 6A, 6B, 6C, 6D, 6E and 6F illustrate several operations in manufacturing a semiconductor device according to some embodiments of the present disclosure.

### PREFERRED EMBODIMENT OF THE PRESENT INVENTION

The following disclosure provides for many different embodiments, or examples, for implementing different features of the provided subject matter. Specific examples of components and arrangements are described below. These are, of course, merely examples and are not intended to be limiting. In the present disclosure, reference to the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Embodiments of the present disclosure are discussed in detail below. It should be appreciated, however, that the present disclosure provides many applicable concepts that can be embodied in a wide variety of specific contexts. The specific embodiments discussed are merely illustrative and do not limit the scope of the disclosure.

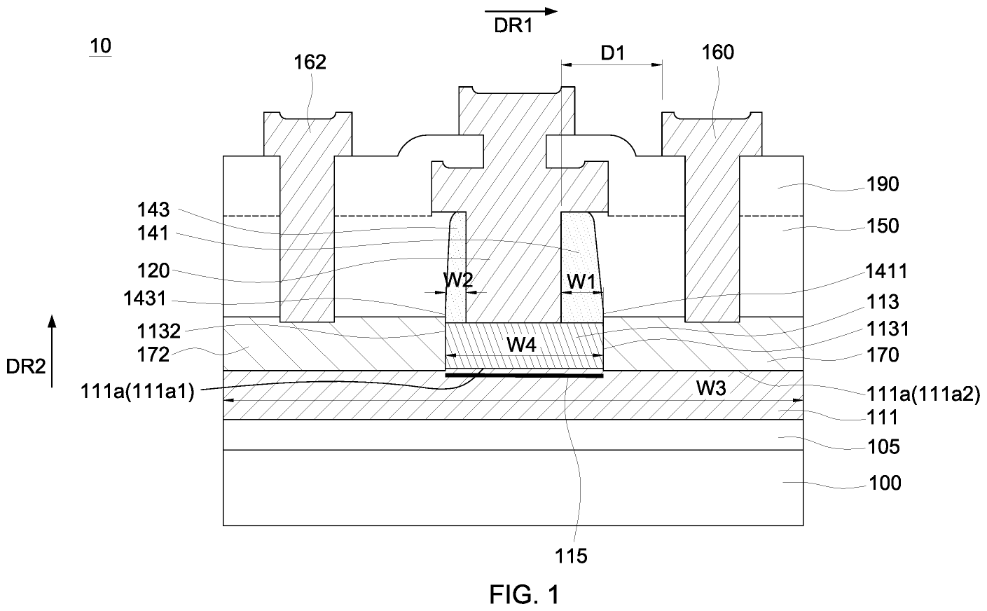

FIG. 1 is a cross-sectional view of a semiconductor device 10 according to some embodiments of the present disclosure. The semiconductor device 10 can work in various voltage levels. For example, the semiconductor device 10 can work in a relatively low voltage level (e.g., lower than about 20V, from about 10 V to about 20 V, and/or from about 5 V to about 10 V). The semiconductor device 10 can have a reduced size which is advantageous for a low power and high speed operation.

The semiconductor device 10 may include a substrate 100, a buffer layer 105, nitride semiconductor layers 111 and 113, a gate structure 120, spacers 141 and 143, dielectric layers 150 and 190, a drain electrode 160, a source electrode 162, and doped group III-V semiconductor layers 170 and 172.

The substrate 100 may include, without limitation, silicon (Si), doped Si, silicon carbide (SiC), germanium suicide (SiGe), gallium arsenide (GaAs), sapphire, silicon on insulator (SOI), or other suitable material(s). The substrate 100 may further include a doped region, for example, a p-well, an n-well, or the like. The substrate 100 may include impurity.

The buffer layer 105 may be formed on the substrate 100. The buffer layer 105 may include, without limitation, a group III-V semiconductor layer. For example, the buffer layer 105 may include a GaN-based epitaxial material.

The nitride semiconductor layer 111 may be formed on the buffer layer 105. The nitride semiconductor layer 111 may include, without limitation, a group III nitride, for example, a compound InₓAl_{y}Ga_{1-x-y}N, in which x+y≤1. The group III nitride may further include, but is not limited to, for example, a compound Al_{y}Ga_{(1-y)}N, in which y≤1. For example, the nitride semiconductor layer 111 may include a GaN layer having a bandgap of about 3.4 eV.

The nitride semiconductor layer 111 has a surface 111a (also referred to as “an upper surface”). The nitride semiconductor layer 111 may have a width W3 substantially in parallel to the surface 111a of the nitride semiconductor layer 111 along a direction DR1. The surface 111a of the nitride semiconductor layer 111 may include portions 111a1 and 111a2. The portion 111a1 of the surface 111a may directly contact the nitride semiconductor layer 113. The portion 111a2 of the surface 111a may be recessed from the portion 111a1 of the surface 111a.

The nitride semiconductor layer 113 may be formed on the surface 111a of the nitride semiconductor layer 111. The nitride semiconductor layer 113 may have a greater bandgap than that of the nitride semiconductor layer 111. The nitride semiconductor layer 113 may be in direct contact with the nitride semiconductor layer 111. The nitride semiconductor layer 113 may include, without limitation, a group III nitride, for example, a compound InₓAl_{y}Ga_{1-x-y}N, in which x+y≤1. The group III nitride may further include, but is not limited to, for example, a compound Al_{y}Ga_{(1-y)}N, in which y≤1. For example, the nitride semiconductor layer 113 may include AlGaN having a band gap of about 4 eV.

A heterojunction may be formed between the nitride semiconductor layer 111 and the nitride semiconductor layer 113, e.g., at an interface of the nitride semiconductor layer 111 and the nitride semiconductor layer 113, and the polarization of the heterojunction of different nitrides forms a two-dimensional electron gas (2DEG) region 115 adjacent to the interface of the nitride semiconductor layer 111 and the nitride semiconductor layer 113. The 2DEG region 115 may be formed in the nitride semiconductor layer 111. The nitride semiconductor layer 111 can provide electrons to or remove electrons from the 2DEG region 115, thereby controlling the conduction of the semiconductor device 10. Although it is not illustrated in FIG. 1 for simplification, however, it is contemplated that a super lattice layer may be formed between the substrate 100 and the nitride semiconductor layer 111 to facilitate operation of the semiconductor device 10 in a relatively high voltage level.

The nitride semiconductor layer 113 may include a surface 1131 (also referred to as “a lateral surface”) and a surface 1132 (also referred to as “a lateral surface”) opposite the surface 1131. The surface 1131 of the nitride semiconductor layer 113 may extend from the nitride semiconductor layer 111 towards the gate structure 120. The surface 1131 of the nitride semiconductor layer 113 may extend along a direction DR2 angled with the direction DR1. The surface 1131 of the nitride semiconductor layer may be angled with the surface 111a of the nitride semiconductor layer 111. The nitride semiconductor layer 113 may have a width W4 along the direction DR1, and the width W3 of the nitride semiconductor layer 111 is greater than the width W4 of nitride semiconductor layer 113. Accordingly, the nitride semiconductor layer 113 having a relatively less width W4 is advantageous to reducing the gate-to-drain length (Lgd) and the gate-to-source length (Lgs), and thus the conduction resistance of the semiconductor device 10 can be reduced.

The gate structure 120 may be disposed on the nitride semiconductor layer 113. The gate structure 120 may include a conductive layer. The gate structure 120 may be or include a gate metal. The gate metal may include, for example, but is not limited to, titanium (Ti), tantalum (Ta), tungsten (W), aluminum (Al), cobalt (Co), copper (Cu), nickel (Ni), platinum (Pt), lead (Pb), molybdenum (Mo) and compounds thereof (such as, but not limited to, titanium nitride (TiN), tantalum nitride (TaN), other conductive nitrides, or conductive oxides), metal alloys (such as aluminum-copper alloy (Al—Cu)), or other suitable materials. The 2DEG region 115 may be formed under the gate structure 120 and preset to be in an ON state when the gate structure 120 is in a zero bias state. Such a device can be referred to as a depletion-mode device.

The spacer 141 may be disposed on the nitride semiconductor layer 113. The spacer 141 may directly contact the gate structure 120. The surface 1131 of the nitride semiconductor layer 113 may be defined by the spacer 141. The surface 1131 of the nitride semiconductor layer 113 may be aligned with the spacer 141. The surface 1131 of the nitride semiconductor layer 113 may be aligned with a surface 1411 (also referred to as “a lateral surface”) of the first spacer 141. The bottom of the spacer 141 may have a width W1 along the direction DR1. The width W1 of the spacer 141 may be equal to or less than about 200 nm. The width W1 of the spacer 141 may be from about 10 nm to about 150 nm. The width W1 of the spacer 141 may be from about 10 nm to about 100 nm.

The spacer 143 may be disposed on the nitride semiconductor layer 113 and spaced apart from the spacer 141 by the gate structure 120. The spacer 143 may directly contact the gate structure 120. The surface 1132 of the nitride semiconductor layer 113 may be defined by the spacer 143. The surface 1132 of the nitride semiconductor layer 113 may be aligned with the spacer 143. The surface 1132 of the nitride semiconductor layer 113 may be aligned with a surface 1431 (also referred to as “a lateral surface”) of the first spacer 143.

The bottom of the spacer 143 may have a width W2 along the direction DR1. The width W2 of the spacer 143 may be equal to or less than about 100 nm. The width W2 of the spacer 143 may be from about 5 nm to about 80 nm. The spacers 141 and 143 may include silicon oxide, silicon nitride, silicon oxynitride, aluminum oxide, aluminum nitride, or a combination thereof. The spacers 141 and 143 may be or include Si₃N₄. The spacer 143 may further include a dopant. The dopant may include fluorine, phosphorus, boron, carbon, silicon, antimony, germanium, aluminum, indium, or a combination thereof.

The width W2 of the spacer 143 may be different from the width W1 of the spacer 141. The width W1 of the spacer 141 may be greater than the width W2 of the spacer 143. The width W1 of the spacer 141 may be greater than the width W2 of the spacer 143 by less than about 30 nm. The width W1 of the spacer 141 may be greater than the width W2 of the spacer 143 by less than about 20 nm. The width W1 of the spacer 141 may be greater than the width W2 of the spacer 143 by less than about 10 nm.

The drain electrode 160 may be disposed relatively adjacent to the spacer 141 than the spacer 143. The drain electrode 160 may be spaced apart from the gate structure 120 by a distance D1. The source electrode 162 may be disposed on a side of the gate structure 120 opposite to the drain electrode 160. The drain electrode 160 and the source electrode 162 may include, for example, without limitation, one or more conductor materials. The conductor materials may include, but are not limited to, for example, metals, alloys, doped semiconductor materials (e.g., doped crystalline silicon), or other suitable conductor materials.

The dielectric layer 150 may be adjacent to the spacer 141. The dielectric layer 150 may directly contact the spacer 141. The dielectric layer 190 may cover the dielectric layer 150 and the spacer 141. The dielectric layer 150 and the dielectric layer 190 may include the same material or different materials. The dielectric layer 150 and the dielectric layer 190 may include silicon oxide, silicon nitride, silicon oxynitride, aluminum oxide, aluminum nitride, or a combination thereof. The dielectric layer 150 and the spacers 141 and 143 may include different materials. The dielectric layer 190 and the spacers 141 and 143 may include different materials. The dielectric layer 150 and the dielectric layer 190 may include silicon oxide.

The doped group III-V semiconductor layer 170 may be formed on the surface 111a of the nitride semiconductor layer 111 and located on a lateral side of the nitride semiconductor layer 113. The doped group III-V semiconductor layer 170 may directly contact the surface 111a of the first nitride semiconductor layer 111. The doped group III-V semiconductor layer 170 may directly contact the portion 111a2 of the surface 111a of the nitride semiconductor layer 111. The doped group III-V semiconductor layer 170 may be connected to the drain electrode 160 and directly contact the nitride semiconductor layer 111. The doped group III-V semiconductor layer 170 may directly contact the surface 1131 (also referred to as “the lateral surface”) of the nitride semiconductor layer 113. The doped group III-V semiconductor layer 170 can reduce the drain ohmic contact resistance, and the parasitic resistance which could have been formed from the nitride semiconductor layer 113 between the drain electrode 160 and the gate structure 120 can be prevented. Therefore, the electrical performance of the semiconductor device 10 can be improved, particularly for the semiconductor device 10 having a relatively small size and working in a relatively low voltage level. In addition, the doped group III-V semiconductor layer 170 directly contacts the nitride semiconductor layer 111 and is located on the lateral surface of the nitride semiconductor layer 113, and thus the gate-to-drain length (Lgd) can be relatively short, and thus the conduction resistance of the semiconductor device 10 can be relatively low.

The distance D1 between the drain electrode 160 and the gate structure 120 may be greater than the distance (i.e., the width W1) between the doped group III-V semiconductor layer 170 and the gate structure 120. When the overall size of the semiconductor device 10 is reduced, the relatively long distance D1 can provide a satisfactory tolerance to voltage for the semiconductor device 10. Therefore, the relatively short distance (i.e., the width W1) between the drain electrode 160 and the gate structure 120 can reduce the conduction resistance of the semiconductor device 10 without adversely affecting the voltage tolerance ability of the semiconductor device 10.

The spacer 141 may be disposed between the gate structure 120 and the doped group III-V semiconductor layer 170. The surface 1411 of the first spacer 141 may be aligned with an interface (i.e., the surface 1131) between the nitride semiconductor layer 113 and the doped group III-V semiconductor layer 170. The spacer 141 may directly contact the nitride semiconductor layer 113 and the doped group III-V semiconductor layer 170.

The doped group III-V semiconductor layer 172 may be formed on the surface 111a of the nitride semiconductor layer 111 and located on a lateral side of the nitride semiconductor layer 113. The doped group III-V semiconductor layer 172 may directly contact the surface 111a of the nitride semiconductor layer 111. The doped group III-V semiconductor layer 172 may directly contact the surface 1132 of the nitride semiconductor layer 113. The second doped group III-V semiconductor layer 172 may be spaced apart from the doped group III-V semiconductor layer 170 by the nitride semiconductor layer 113. The doped group III-V semiconductor layer 172 can reduce the source ohmic contact resistance, and the parasitic resistance which could have been formed from the nitride semiconductor layer 113 between the source electrode 162 and the gate structure 120 can be prevented. In addition, the doped group III-V semiconductor layer 172 directly contacts the nitride semiconductor layer 111 and is located on the lateral surface of the nitride semiconductor layer 113, and thus the gate-to-source length (Lgs) can be relatively short, and thus the conduction resistance of the semiconductor device 10 can be relatively low.

The doped group III-V semiconductor layer 170 and the doped group III-V semiconductor layer 172 may be located on two lateral sides of the nitride semiconductor layer 113. Accordingly, the drain ohmic contact resistance and the source ohmic contact resistance can be reduced. In addition, the gate-to-drain length (Lgd) and the gate-to-source length (Lgs) can be relatively short, and thus the conduction resistance of the semiconductor device 10 can be reduced. The distance (i.e., the width W1) between the doped group III-V semiconductor layer 170 and the gate structure 120 may be different from a distance (i.e., the width W2) between the doped group III-V semiconductor layer 172 and the gate structure 120.

The doped group III-V semiconductor layers 170 and 172 may be or include n-type doped group III-V semiconductor layers. The doped group III-V semiconductor layers 170 and 172 may be made of or include an epitaxial n-type III-V material. The doped group III-V semiconductor layers 170 and 172 may include, for example, but are not limited to, group III nitride, for example, a compound Al_{y}Ga_{(1-y)}N, in which y≤1. A material of the doped group III-V semiconductor layers 170 and 172 may be or include n-type doped GaN.

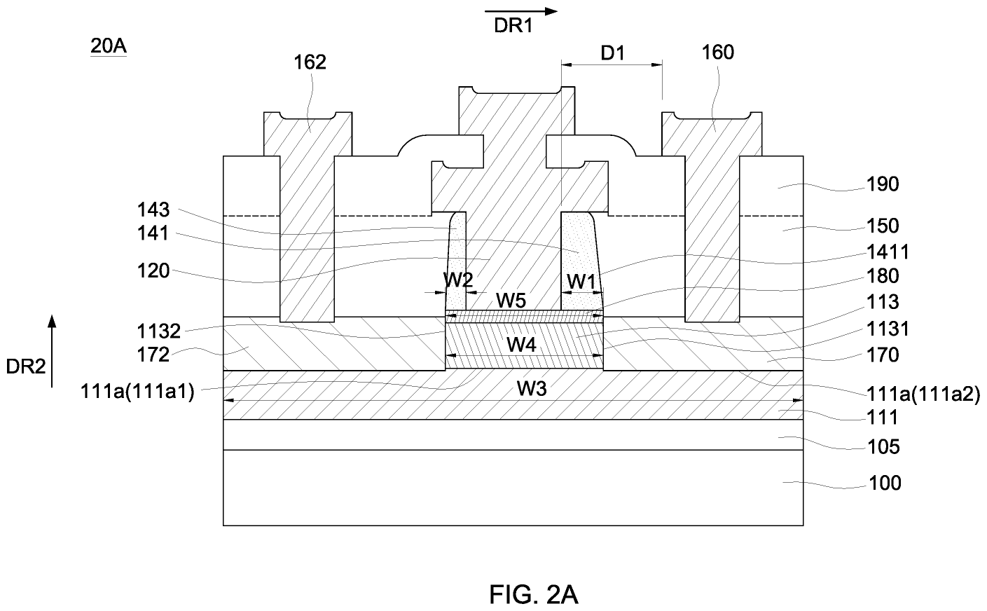

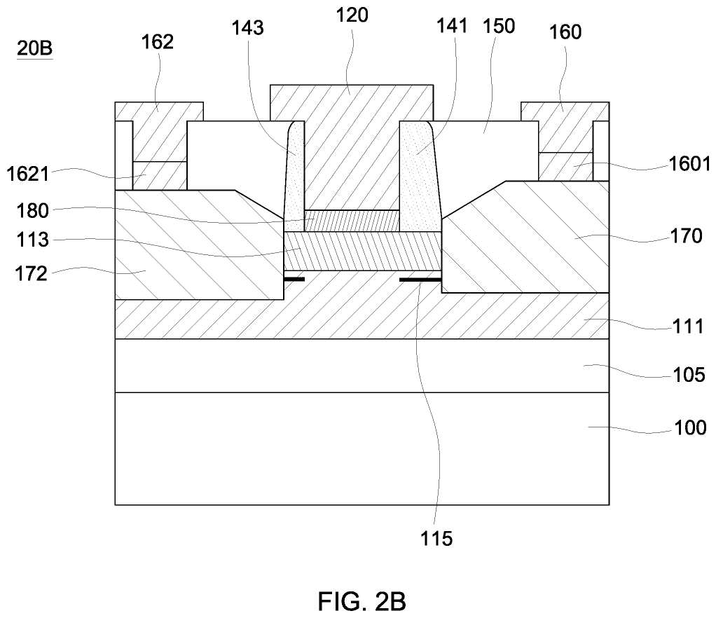

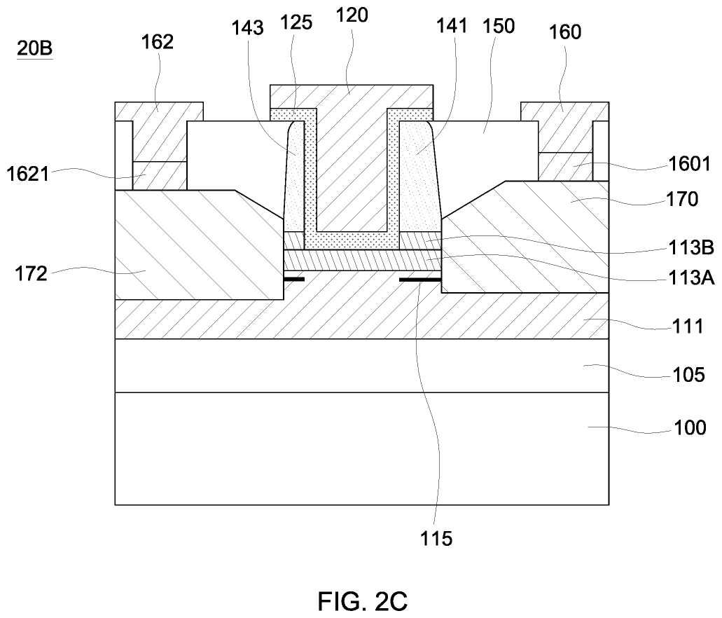

FIG. 2A is a cross-sectional view of a semiconductor device 20A according to some embodiments of the present disclosure. The semiconductor device 20A has a structure similar to the semiconductor device 10 shown in FIG. 1, except that, for example, the semiconductor device 20A may further include a doped group III-V semiconductor layer 180.

The doped group III-V semiconductor layer 180 may be over the nitride semiconductor layer 113. The doped group III-V semiconductor layer 180 may directly contact the doped group III-V semiconductor layer 170. The doped group III-V semiconductor layer 180 may directly contact the doped group III-V semiconductor layer 172. The doped group III-V semiconductor layer 180 may directly contact the gate structure 120.

The 2DEG region 115 formed under the doped group III-V semiconductor layer 180 may be preset to be in an OFF state when the gate structure 120 is in a zero-bias state. When a voltage is applied to the gate structure 120, electrons or charges are induced in the 2DEG region 115 below the gate structure 120. When the voltage increases, the number of induced electrons or charges increases as well. Such a device can be referred to as an enhancement-mode device.

The doped group III-V semiconductor layer 180 may have a width W5 substantially in parallel to the surface 111a of the nitride semiconductor layer 111 along the direction DR1. The width W4 of the nitride semiconductor layer 113 and the width W5 of the doped group III-V semiconductor layer 180 may be substantially the same.

The doped group III-V semiconductor layer 180 may be or include a p-type doped group III-V layer. The doped group III-V semiconductor layer 180 may be made of or include an epitaxial p-type III-V material. The doped group III-V semiconductor layer 180 may include, for example, but is not limited to, group III nitride, for example, a compound Al_{y}Ga_{(1-y)}N, in which y≤1. A material of the doped group III-V semiconductor layer 180 may be or include p-type doped GaN. The doped group III-V semiconductor layer 170 and the doped group III-V semiconductor layer 172 may have a first polarity, and the doped group III-V semiconductor layer 180 may have a second polarity opposite the first polarity. For example, the doped group III-V semiconductor layer 170 and the doped group III-V semiconductor layer 172 may be or include n-type doped GaN, and the doped group III-V semiconductor layer 180 may be or include p-type doped GaN.

FIG. 2B is a cross-sectional view of a semiconductor device 20B according to some embodiments of the present disclosure. The semiconductor device 20B has a structure similar to the semiconductor device 20A shown in FIG. 2A, except that, for example, the doped group III-V semiconductor layer 170 and the doped group III-V semiconductor layer 172 may have a different arrangement.

Upper surfaces of the doped group III-V semiconductor layer 170 and the doped group III-V semiconductor layer 172 may be at elevations higher than that of the doped group III-V semiconductor layer 180. The doped group III-V semiconductor layer 170 may directly contact the spacer 141. The doped group III-V semiconductor layer 172 may directly contact the spacer 143. The dielectric layer 150 may be spaced apart from the doped group III-V semiconductor layer 180 by the spacers 141 and 143.

The semiconductor device 20B may include an ohmic contact 1601 connecting the drain electrode 160 and the doped group III-V semiconductor layer 170. The semiconductor device 20B may include an ohmic contact 1621 connecting the source electrode 162 and the doped group III-V semiconductor layer 172.

FIG. 2C is a cross-sectional view of a semiconductor device 20C according to some embodiments of the present disclosure. The semiconductor device 20C has a structure similar to the semiconductor device 10 shown in FIG. 1, except that, for example, the nitride semiconductor layer 113 of the semiconductor device 20C may have a different structure.

The nitride semiconductor layer 113 may include sub-layers 113A and 113B. The sub-layer 113A may directly contact the nitride semiconductor layer 111, and the sub-layer 113B may directly contact the sub-layer 113A. A thickness of the sub-layer 113A may be less than a thickness of the sub-layer 113B. The thickness of the sub-layer 113A may be equal to or less than about 2 nm. The thickness of the sub-layer 113A may be about 1 nm. The thickness of the sub-layer 113B may be about 2 nm to about 5 nm. The thickness of the sub-layer 113B may be about 3 nm to about 4 nm. A resistance of the sub-layer 113A may be lower than a resistance of the sub-layer 113B. A difference between the resistance of the sub-layer 113A and the resistance of the sub-layer 113B may be equal to or greater than about 50Ω/□. A difference between the resistance of the sub-layer 113A and the resistance of the sub-layer 113B may be equal to or greater than about 100Ω/□. The resistance of the sub-layer 113A may be equal to or less than 300Ω/□. The resistance of the sub-layer 113A may be equal to or less than 250Ω/□.

The sub-layer 113A and the sub-layer 113B may include different materials. The sub-layer 113A may include a compound Al_{y}Ga_{(1-y)}N, in which y≤1. For example, the sub-layer 113A may be or include AN. The sub-layer 113B may include a compound doped-Al_{y}Ga_{(1-y)}N, in which y≤1. The sub-layer 113B may include a compound InₓAl_{y}Ga_{1-x-y}N, in which x+y≤1 and x>0. For example, the sub-layer 113B may be or include InAlN.

A heterojunction may be formed between the nitride semiconductor layer 111 and the nitride semiconductor sub-layer 113A to form the 2DEG region 115. The sub-layer 113A having a relatively low resistance can be advantageous to the reduction of the conduction resistance. While the sub-layer 113A is relatively thin, the nitride semiconductor sub-layer 113B may serve to boost the formation of the 2DEG region 115 between the nitride semiconductor layer 111 and the nitride semiconductor layer 113.

The semiconductor device 20C may further include a gate dielectric 125 between the gate structure 120 and the nitride semiconductor layer 113. The sub-layer 113B of the nitride semiconductor layer 113 may define an opening exposing a portion of the sub-layer 113A. The gate dielectric 125 may extend into the opening of the sub-layer 113B. The gate dielectric 125 may directly contact the sub-layer 113A. The gate structure 120 may be spaced apart from the sub-layer 113A of the nitride semiconductor layer 113 by the gate dielectric 125. The spacers 141 and 143 may directly contact the sub-layer 113B. The spacers 141 and 143 may be spaced apart from the sub-layer 113A by the sub-layer 113B. The gate dielectric 125 may serve to prevent current leakage through the relatively thin nitride semiconductor sub-layer 113A. The region where the gate dielectric 125 directly contacts the nitride semiconductor sub-layer 113A may form a normally-off channel region.

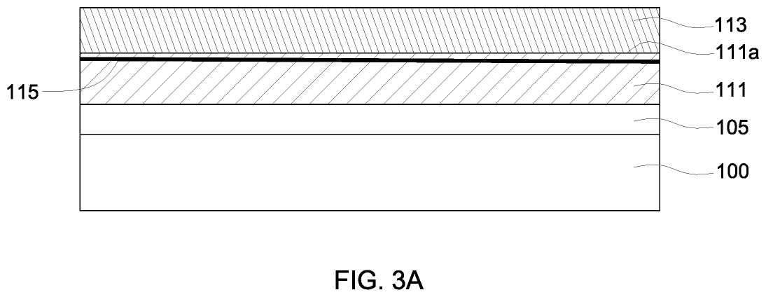

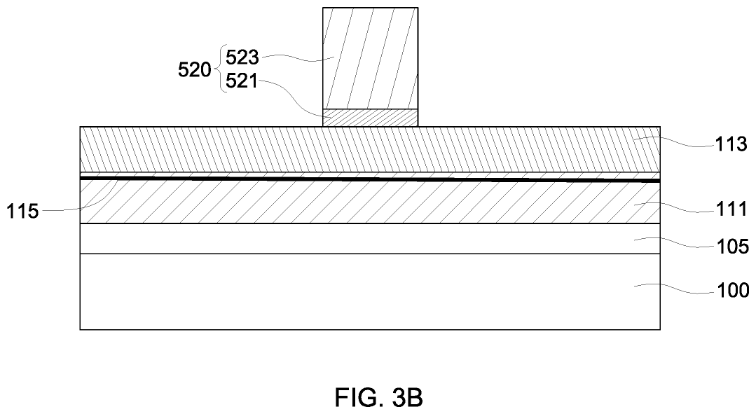

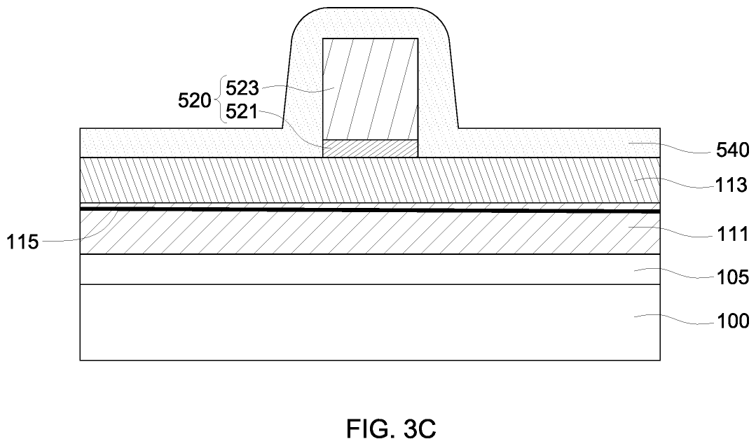

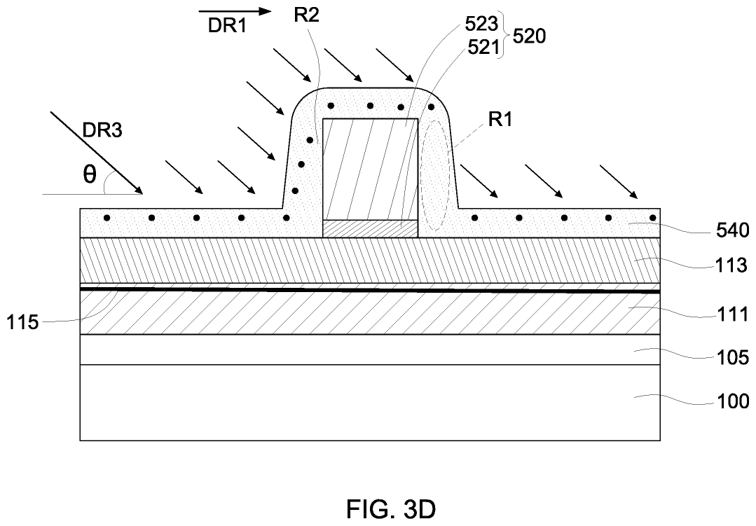

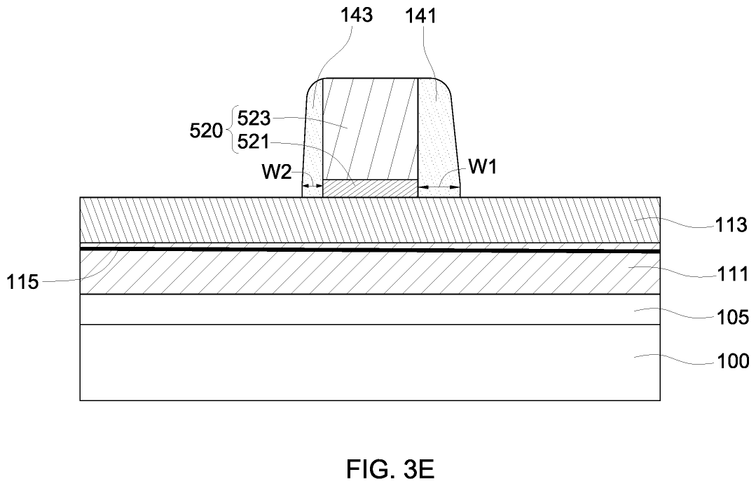

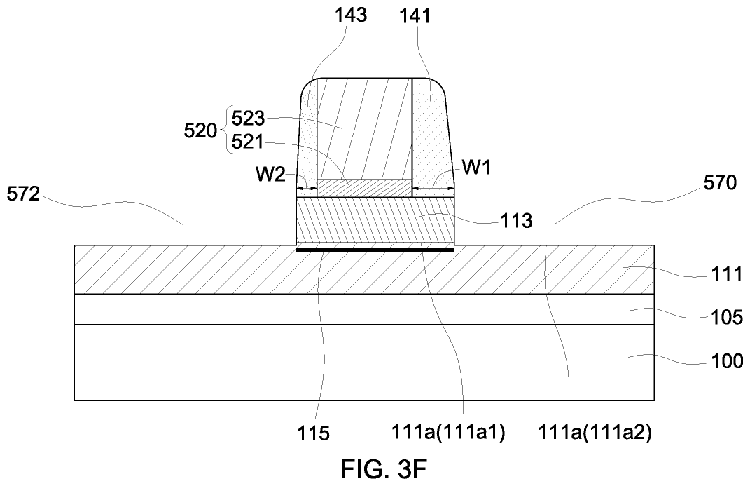

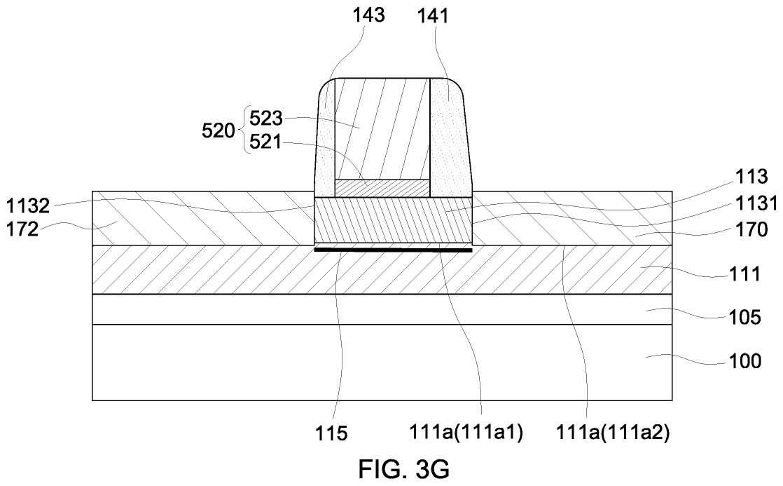

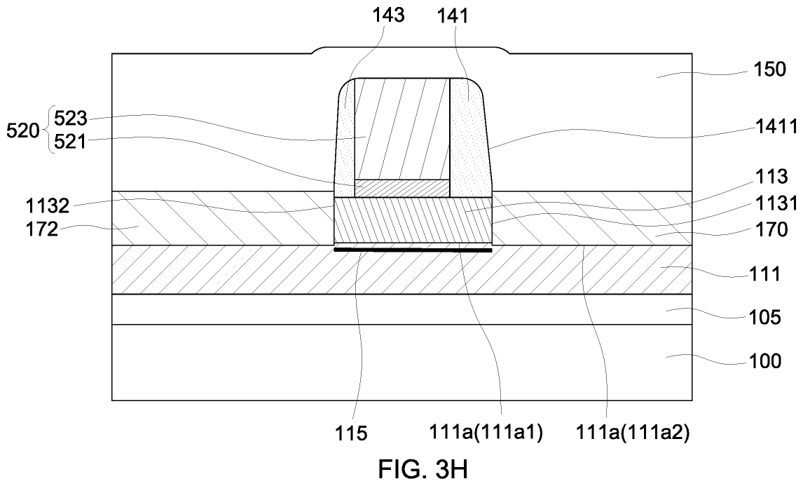

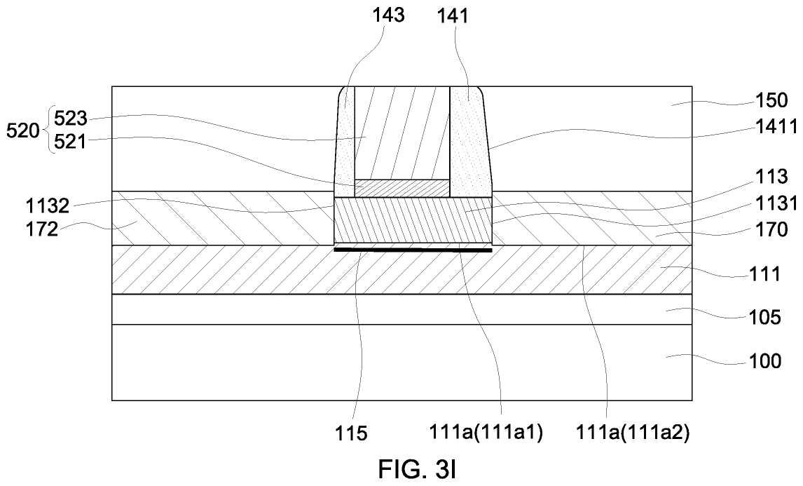

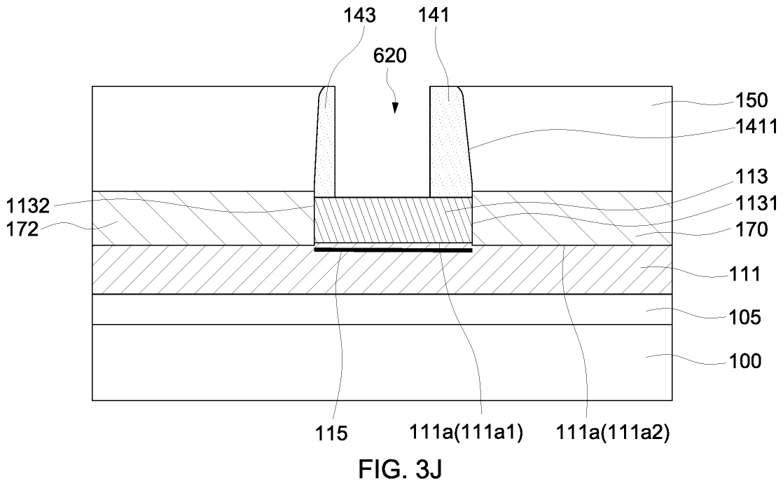

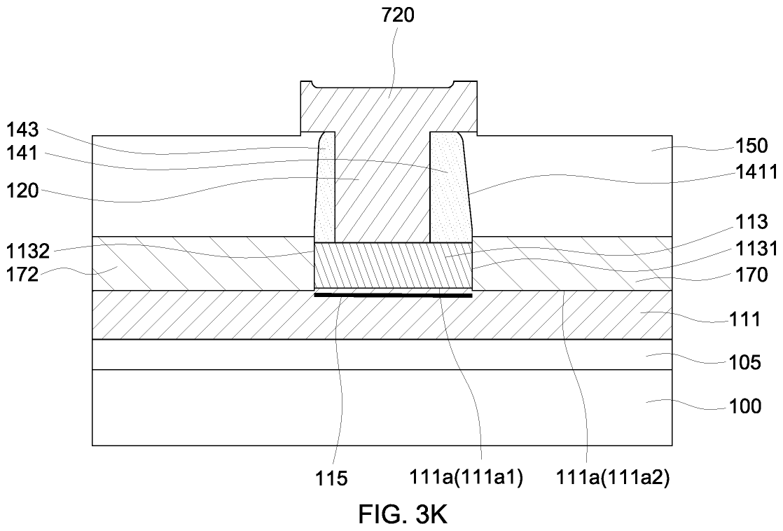

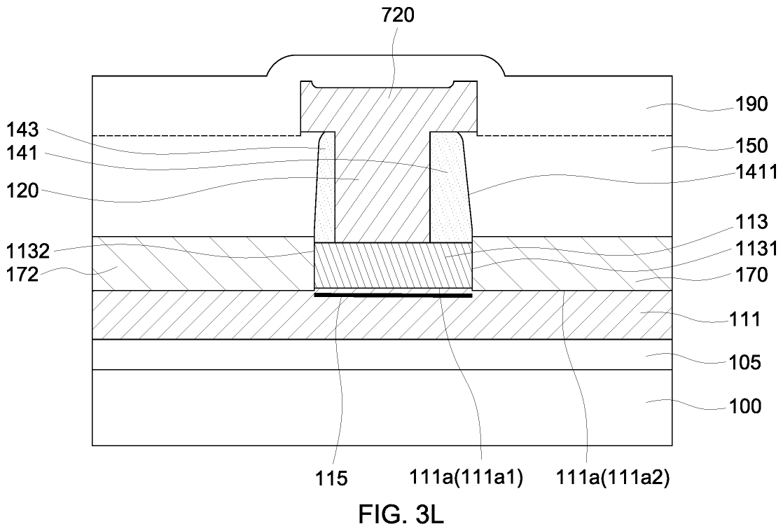

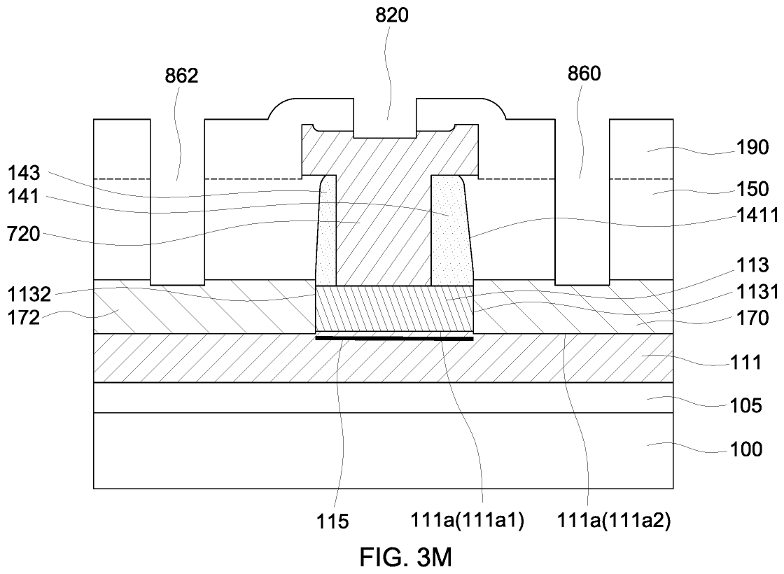

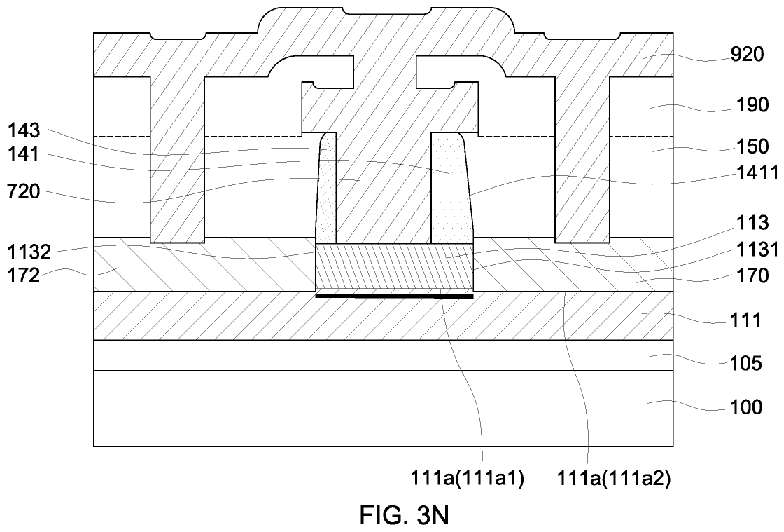

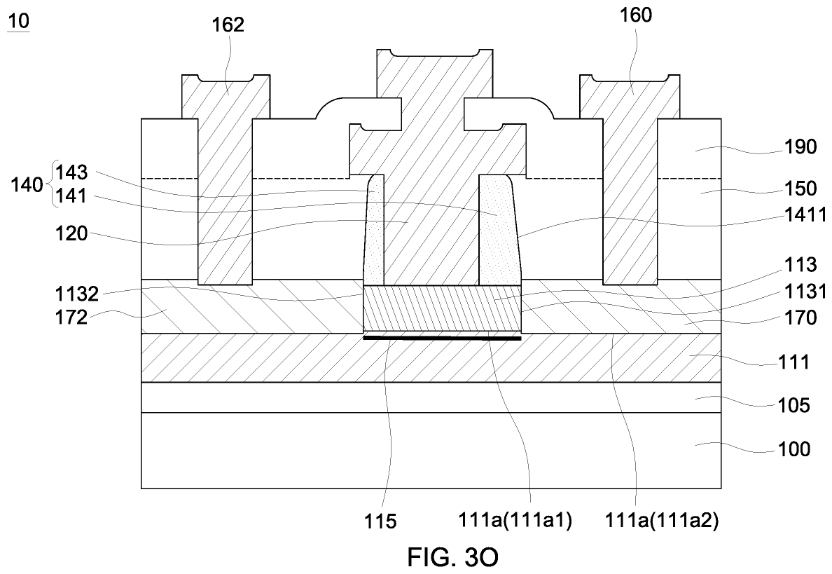

FIGS. 3A, 3B, 3C, 3D, 3E, 3F, 3G, 3H, 3I, 3J, 3K, 3L, 3M, 3N and 3O illustrate several operations in manufacturing a semiconductor device 10 according to some embodiments of the present disclosure.

Referring to FIG. 3A, a buffer layer 105 may be formed on a substrate 100, and a nitride semiconductor layer 111 may be formed on buffer layer 105. A nitride semiconductor layer 113 having a greater bandgap than that of the nitride semiconductor layer 111 may be formed on and in direct contact with a surface 111a of the nitride semiconductor layer 111. The buffer layer 105 and the nitride semiconductor layers 111 and 113 may be formed by epitaxial growth. As a heterojunction can be formed between the nitride semiconductor layer 111 and the nitride semiconductor layer 113, e.g., at an interface of the nitride semiconductor layer 111 and the nitride semiconductor layer 113, a 2DEG region 115 may be formed adjacent to the interface of the nitride semiconductor layer 111 and the nitride semiconductor layer 113.

Referring to FIG. 3B, a dummy gate structure 520 may be formed on the nitride semiconductor layer 113. The dummy gate structure 520 may be formed by the following operations: forming a silicon-containing layer 521 on the nitride semiconductor layer 113, and forming a metal-containing layer 523 on the silicon-containing layer 521. The silicon-containing layer 521 may be or include a silicon layer. The metal-containing layer 523 may be or include a metal oxide layer, a metal nitride layer, or a combination thereof. The metal-containing layer 523 may be or include Al₂O₃, AN, or a combination thereof. The silicon-containing layer 521 and the metal-containing layer 523 may be formed by a deposition technique followed by a patterning technique.

Referring to FIG. 3C, a passivation layer 540 may be formed on the nitride semiconductor layer 113 and the dummy gate structure 520. The passivation layer 540 may have a thickness of about 10 nm to about 1000 nm. The passivation layer 540 may be formed by a deposition process, such as a CVD process. The passivation layer 540 may be or include silicon oxide, silicon nitride, silicon oxynitride, aluminum oxide, aluminum nitride, or a combination thereof. The passivation layer 540 may be or include Si₃N₄.

Referring to FIG. 3D, a dopant may be formed into the passivation layer 540. The dopant may be implanted into the passivation layer 540. The dopant may be implanted from a direction DR3, and the direction DR3 may be angled with the direction DR1. An angle θ between the direction DR1 and the direction DR3 may be from about 15° to about 90°. An angle (i.e., the angle θ) between the direction DR3 and the surface 111a of the nitride semiconductor layer 111 may be from about 15° to about 90°. Due to the tilted implantation angle, a portion R1 of the passivation layer 540 may be blocked by the dummy gate structure 520 from being implanted with the dopant. The dopant concentrations of portions (e.g., portions R1 and R2) of the passivation layer 540 on two lateral sides of the dummy gate structure 520 may be different. The region R1 of the passivation layer 540 may have a relatively low dopant concentration.

Referring to FIG. 3E, the passivation layer 540 may be etched anisotropically to remove a portion of the passivation layer 540 and form spacers 141 and 143 on two lateral sides of the dummy gate structure 520. Due to the difference in dopant concentrations of the portions (e.g., portions R1 and R2) of the passivation layer 540 on two lateral sides of the dummy gate structure 520, the portion R1 with a relatively low dopant concentration may have a relatively low etching rate, and the portion R2 with a relatively high dopant concentration may have a relatively high etching rate. As such, the as-formed spacer 141 corresponding to the portion R1 may have a relatively greater width W1, and the as-formed spacer 143 corresponding to the portion R2 may have a relatively less width W2.

Currently, the alignment deviation or tolerance for a photolithography process may be from about 30 nm to about 100 nm, and such alignment deviation or tolerance may adversely affect the device having a reduced size (e.g., having a gate-to-drain length of about 100 nm). With the aforesaid operations of forming regions R1 and R2 having different etching rates resulted from the different dopant concentrations, the spacers 141 and 143 having relatively small widths W1 and W2 can be formed by anisotropically etching the portions R1 and R2 without performing a photolithography process. Accordingly, the formation of the semiconductor device 10 can be prevented from being adversely affected by the alignment deviation or tolerance of a photolithography process.

Referring to FIG. 3F, recesses 570 and 572 may be formed by etching the nitride semiconductor layer 113 in a self-aligned process. The spacers 141 and 143 may be used as a mask to remove portions of the nitride semiconductor layer 113 exposed from the spacers 141 and 143 so as to form the recesses 570 and 572 over the nitride semiconductor layer 111. The nitride semiconductor layer 113 may be etched to form the recess 570 and the recess 572 that self-align to the spacer 141 and the spacer 143, respectively. Portions of the nitride semiconductor layer 111 under the portions of the nitride semiconductor layer 113 exposed from the spacers 141 and 143 may be over-etched and removed to form a portion 111a2 of the surface 111a of the nitride semiconductor layer 111 that is recessed from the portion 111a1 of the surface 111a of the nitride semiconductor layer 111.

Referring to FIG. 3G, a doped group III-V semiconductor layer 170 is formed in the recess 570, and a doped group III-V semiconductor layer 172 is formed in the recess 572. The doped group III-V semiconductor layers 170 and 172 may be formed on the portion 111a2 of the surface 111a of the nitride semiconductor layer 111. The doped group III-V semiconductor layers 170 and 172 may be formed by epitaxial growth. With the recesses 570 and 572 formed by etching the nitride semiconductor layer 113 in a self-aligned process, the doped group III-V semiconductor layers 170 and 172 can be formed to align with the spacers 141 and 143, and thus the gate-to-drain length (Lgd) and the gate-to-source length (Lgs) can be defined by the widths W1 and W2 without performing a photolithography process. Accordingly, the formation of the semiconductor device 10 can be prevented from being adversely affected by the alignment deviation or tolerance of a photolithography process.

Referring to FIG. 3H, a dielectric layer 150 may be formed over the dummy gate structure 520, the spacers 141 and 143, and the doped group III-V semiconductor layers 170 and 172. The dielectric layer 150 may be formed by a deposition process.

Referring to FIG. 3I, a portion of the dielectric layer 150 may be removed to expose the metal-containing layer 523 of the dummy gate structure 520. The portion of the dielectric layer 150 may be removed to expose the spacers 141 and 143. A portion of the metal-containing layer 523 may be removed in the same operation for removing a portion of the dielectric layer 150. The portion of the dielectric layer 150 may be removed by a chemical mechanical polishing (CMP) process.

Referring to FIG. 3J, the dummy gate structure 520 may be removed to form a trench 620 defined by the spacers 141 and 143. The dummy gate structure 520 may be removed by the following operations: using a first etchant to remove the metal-containing layer 523, and using a second etchant to remove the silicon-containing layer 521. The first etchant may have a relatively high etching selectivity of the metal-containing layer 523 to the silicon-containing layer 521. The second etchant may have a relatively high etching selectivity of the silicon-containing layer 521 to the nitride semiconductor layer 113. The first etchant for etching the metal-containing layer 523 may include a chlorine-containing etchant. The second etchant for etching the silicon-containing layer 521 may include a fluorine-containing etchant.

Referring to FIG. 3K, a gate material 720 may be formed in the trench 620 on the nitride semiconductor layer 113. The gate material 720 may be formed by a physical vapor deposition (PVD) process or any suitable deposition process.

Referring to FIG. 3L, a dielectric layer 190 may be formed over the gate material 720 and the dielectric layer 150. The dielectric layer 190 may be formed by a deposition process.

Referring to FIG. 3M, a trench 860 may be formed penetrating the dielectric layers 150 and 190 to expose a portion of the doped group III-V semiconductor layer 170. A trench 862 may be formed penetrating the dielectric layers 150 and 190 to expose a portion of the doped group III-V semiconductor layer 172. A trench 820 may be formed penetrating the dielectric layer 190 to expose a portion of the gate material 720. The trenches 820, 860 and 862 may be formed by the following operations: disposing a patterned etch mask over the dielectric layer 190; etching the dielectric layers 150 and 190 using the patterned etch mask to remove portions of the dielectric layers 150 and 190 to expose the portion of the gate material 720, the portion of the doped group III-V semiconductor layer 170, and the portion of the doped group III-V semiconductor layer 172; and removing the patterned etch mask.

Referring to FIG. 3N, a conductive material 920 may be formed in the trenches 820, 860 and 862 and over the dielectric layer 190. The conductive material 920 may directly contact the gate material 720, the portion of the doped group III-V semiconductor layer 170, and the portion of the doped group III-V semiconductor layer 172. The conductive material 920 may be formed by a physical vapor deposition (PVD) process or any suitable deposition process.

Referring to FIG. 3O, a patterning technique may be performed on the conductive material 920 to form a drain electrode 160, a source electrode 162, and a gate structure 120. The patterning technique may be performed by disposing a patterned etch mask over the conductive material 920; etching the conductive material 920 using the patterned etch mask to remove portions of the conductive material 920, so as to form the drain electrode 160, the source electrode 162, and the gate structure 120; and removing the patterned etch mask. As such, the semiconductor device 10 illustrated in FIG. 1 is formed.

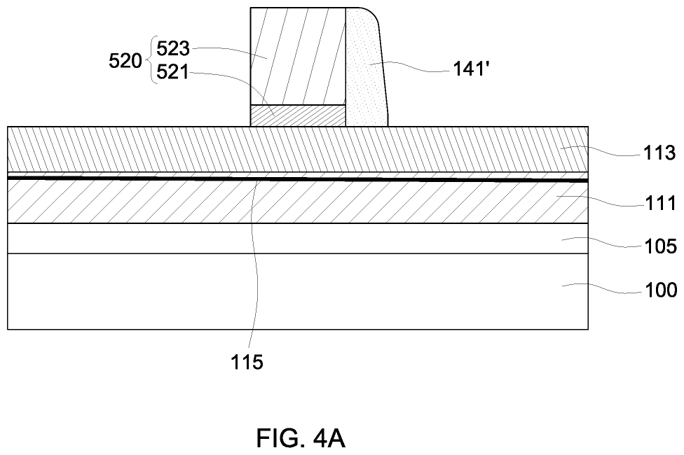

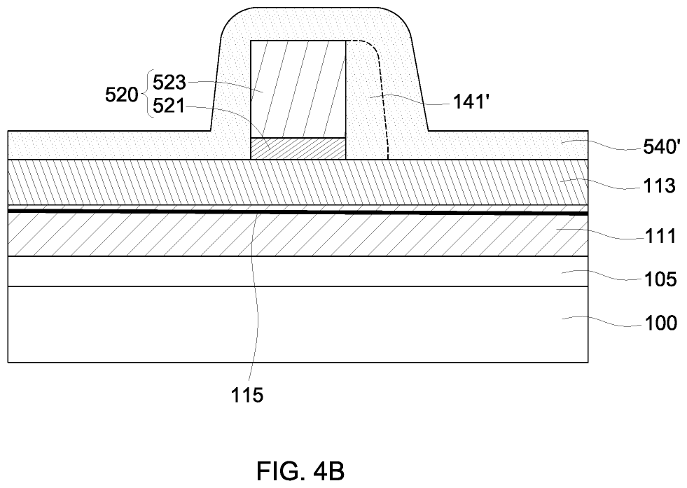

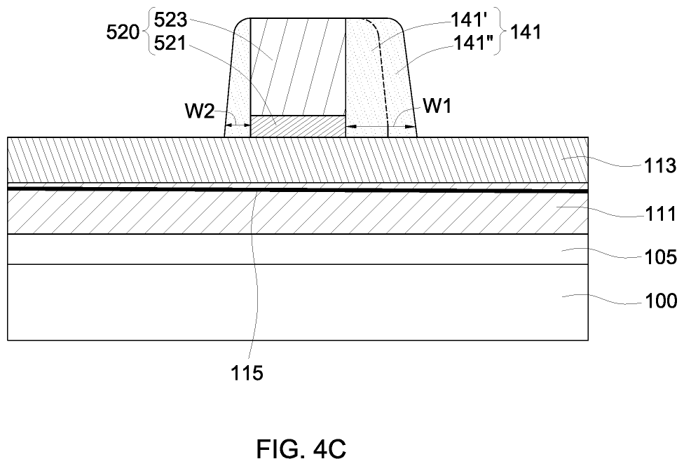

FIGS. 4A, 4B and 4C illustrate several operations in manufacturing a semiconductor device 10 according to some embodiments of the present disclosure.

Operations similar to those illustrated in FIGS. 3A-3D are performed to obtain a structure similar to that illustrated in FIG. 3D.

Referring to FIG. 4A, the passivation layer 540 may be etched anisotropically to remove a portion of the passivation layer 540 and form a spacer 141′ on a lateral side of the dummy gate structure 520. Due to the difference in dopant concentrations of the portions (e.g., portions R1 and R2 illustrated in FIG. 3D) of the passivation layer 540 on two lateral sides of the dummy gate structure 520, the portion R1 with a relatively low dopant concentration may have a relatively low etching rate, and the portion R2 with a relatively high dopant concentration may have a relatively high etching rate and may be fully etched away.

Referring to FIG. 4B, a passivation layer 540′ may be formed on the nitride semiconductor layer 113, the dummy gate structure 520, and the spacer 141′. The passivation layer 540′ may have a thickness of about 10 nm to about 1000 nm. The passivation layer 540′ may be formed by a deposition process, such as a CVD process. The passivation layer 540′ may be or include silicon oxide, silicon nitride, silicon oxynitride, aluminum oxide, aluminum nitride, or a combination thereof. The passivation layer 540′ may be or include Si₃N₄. A dopant formation operation similar to that illustrated in FIG. 3D may be performed on the passivation layer 540′.

Referring to FIG. 4C, the passivation layer 540′ may be etched anisotropically to remove a portion of the passivation layer 540′ and form spacers' 141″ and 143 on two lateral sides of the dummy gate structure 520. The spacer 141″ may be formed on the spacer 141′ to form a spacer 141. As such, the as-formed spacer 141 corresponding to the portion R1 may have a relatively greater width W1, and the as-formed spacer 143 corresponding to the portion R2 may have a relatively less width W2.

Next, operations similar to those illustrated in FIGS. 3F-3O are performed on the structure illustrated in FIG. 4C. As such, the semiconductor device 10 illustrated in FIG. 1 is formed.

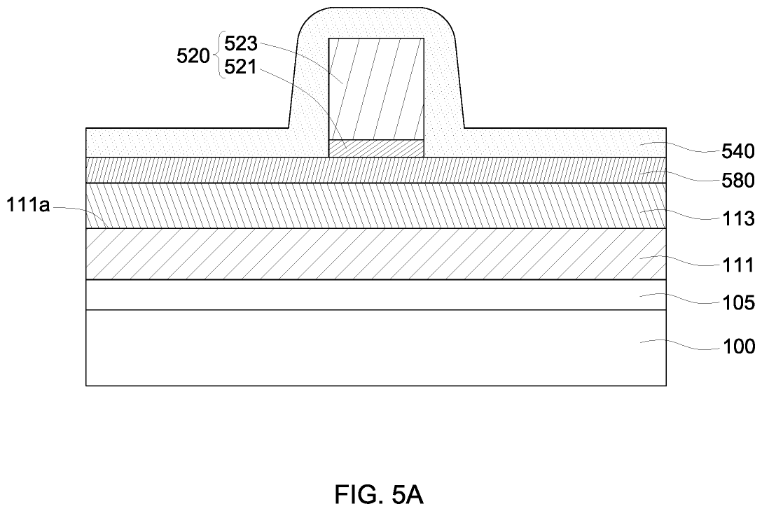

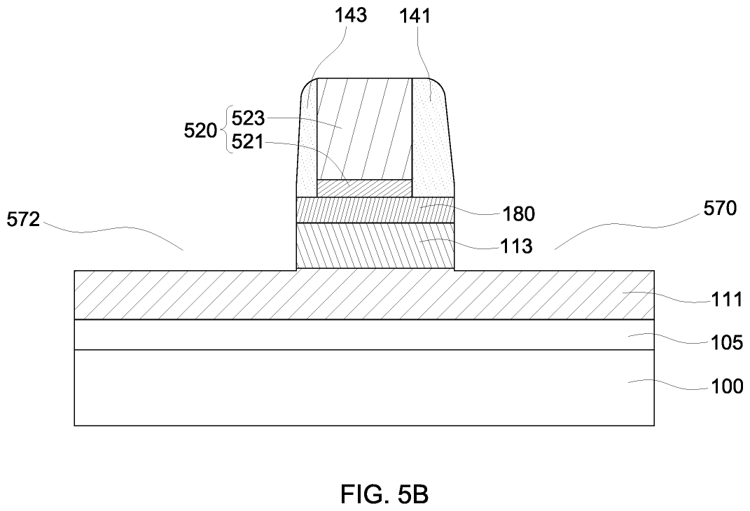

FIGS. 5A and 5B illustrate several operations in manufacturing a semiconductor device 20A according to some embodiments of the present disclosure.

Referring to FIG. 5A, a buffer layer 105 may be formed on a substrate 100, a nitride semiconductor layer 111 may be formed on buffer layer 105, a nitride semiconductor layer 113 having a greater bandgap than that of the nitride semiconductor layer 111 may be formed on and in direct contact with a surface 111a of the nitride semiconductor layer 111, and a doped group III-V semiconductor layer 180 may be formed on the nitride semiconductor layer 113. The buffer layer 105, the nitride semiconductor layers 111 and 113, and the doped group III-V semiconductor layer 180 may be formed by epitaxial growth.

Next, still referring to FIG. 5A, a dummy gate structure 520 may be formed on the doped group III-V semiconductor layer 180, and a passivation layer 540 may be formed on the doped group III-V semiconductor layer 180 and the dummy gate structure 520. Next, a dopant formation operation similar to that illustrated in FIG. 3D may be performed on the passivation layer 540, and the passivation layer 540 may be etched anisotropically to remove a portion of the passivation layer 540 and form spacers 141 and 143 on two lateral sides of the dummy gate structure 520 by operations similar to those illustrated in FIG. 3E.

Referring to FIG. 5B, recesses 570 and 572 may be formed by etching the doped group III-V semiconductor layer 180 and the nitride semiconductor layer 113 in a self-aligned process. The spacers 141 and 143 may be used as a mask to remove portions of the doped group III-V semiconductor layer 180 and the nitride semiconductor layer 113 exposed from the spacers 141 and 143 so as to form the recesses 570 and 572 over the nitride semiconductor layer 111.

Next, operations similar to those illustrated in FIGS. 3G-3O are performed on the structure illustrated in FIG. 5B. As such, the semiconductor device 20A illustrated in FIG. 2A is formed.

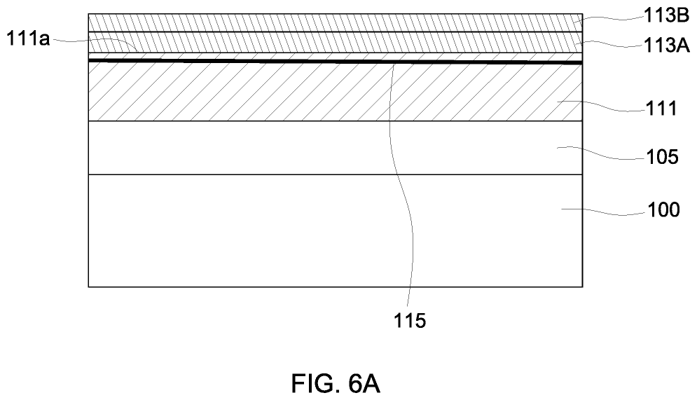

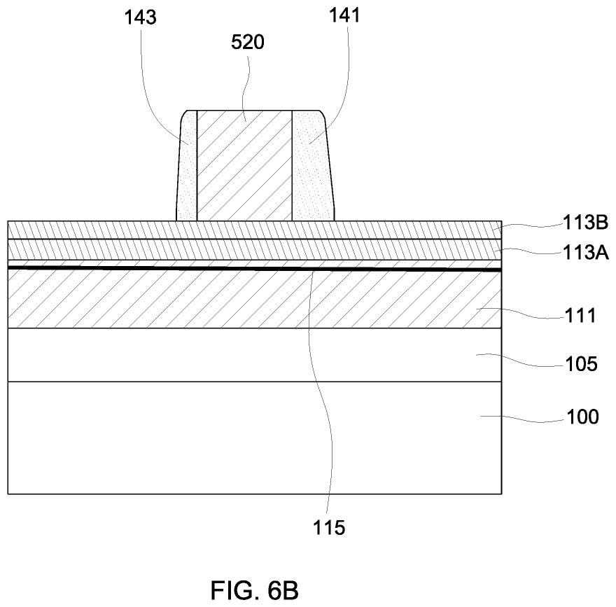

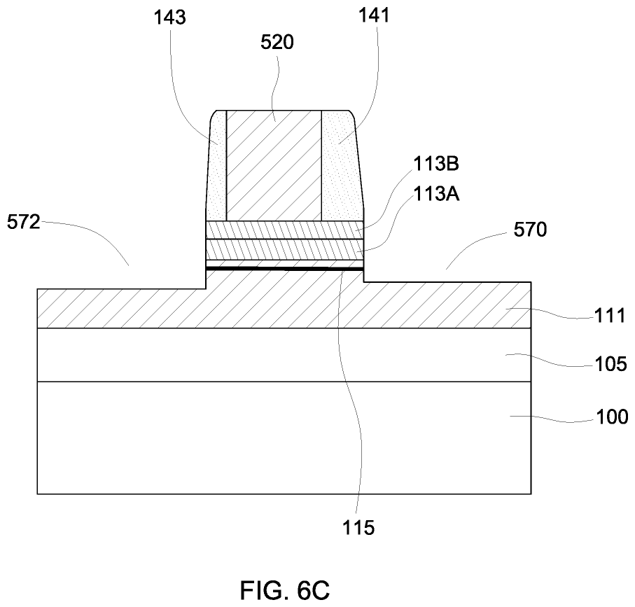

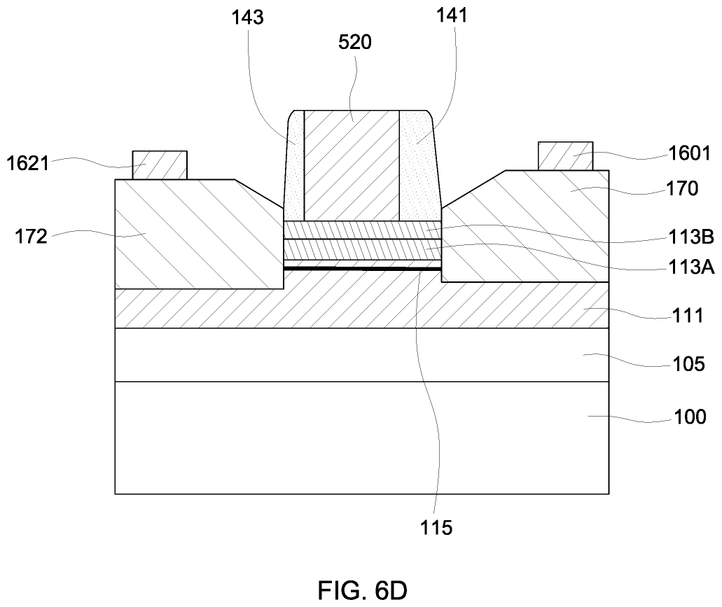

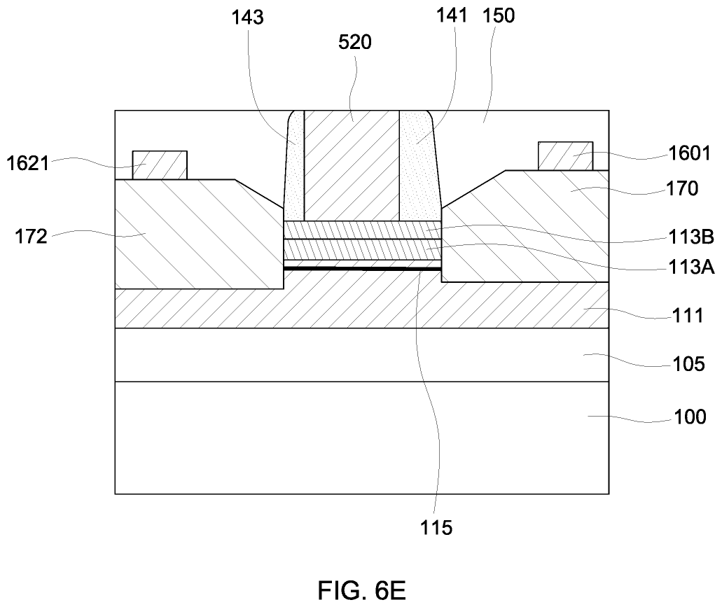

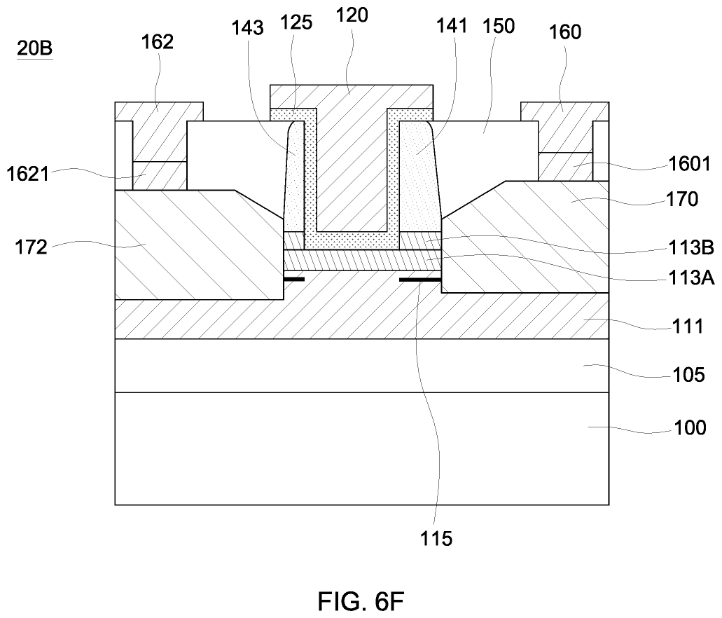

FIGS. 6A, 6B, 6C, 6D, 6E and 6F illustrate several operations in manufacturing a semiconductor device 20C according to some embodiments of the present disclosure.

Referring to FIG. 6A, a buffer layer 105 may be formed on a substrate 100, and a nitride semiconductor layer 111 may be formed on buffer layer 105. A nitride semiconductor sub-layer 113A having a greater bandgap than that of the nitride semiconductor layer 111 may be formed on and in direct contact with a surface 111a of the nitride semiconductor layer 111, and a nitride semiconductor sub-layer 113B may be formed on the nitride semiconductor sub-layer 113A. The sub-layers 113A and 113B form a nitride semiconductor layer 113. The buffer layer 105, the nitride semiconductor layer 111, and the nitride semiconductor sub-layers 113A and 113B may be formed by epitaxial growth. The materials of the nitride semiconductor sub-layers 113A and 113B may be as described above and the description thereof is omitted hereinafter.

Referring to FIG. 6B, operations similar to those illustrated in FIGS. 3B-3E may be performed to form a dummy gate structure 520 and spacers 141 and 143 on the nitride semiconductor sub-layer 113B.

Referring to FIG. 6C, recesses 570 and 572 may be formed by etching the nitride semiconductor sub-layers 113A and 113B in a self-aligned process. The spacers 141 and 143 may be used as a mask to remove portions of the nitride semiconductor sub-layers 113A and 113B exposed from the spacers 141 and 143 so as to form the recesses 570 and 572 over the nitride semiconductor layer 111. The nitride semiconductor sub-layers 113A and 113B may be etched to form the recess 570 and the recess 572 that self-align to the spacer 141 and the spacer 143, respectively. Portions of the nitride semiconductor layer 111 under the portions of the nitride semiconductor sub-layers 113A and 113B exposed from the spacers 141 and 143 may be over-etched and removed to form a portion 111a2 of the surface 111a of the nitride semiconductor layer 111 that is recessed from the portion 111a1 of the surface 111a of the nitride semiconductor layer 111.

Referring to FIG. 6D, a doped group III-V semiconductor layer 170 is formed in the recess 570, and a doped group III-V semiconductor layer 172 is formed in the recess 572. The doped group III-V semiconductor layers 170 and 172 may be formed by epitaxial growth.

Referring to FIG. 6E, an ohmic contact 1601 may be formed on the doped group III-V semiconductor layer 170, and an ohmic contact 1621 may be formed on the doped group III-V semiconductor layer 172. A dielectric layer 150 may be formed over the dummy gate structure 520, the spacers 141 and 143, the ohmic contacts 1601 and 1621, and the doped group III-V semiconductor layers 170 and 172.

Referring to FIG. 6E, operations similar to those illustrated in FIGS. 3I to 3O are performed on the structure illustrated in FIG. 6D. As such, the semiconductor device 20C illustrated in FIG. 2C is formed.

As used herein, spatially relative terms, such as “beneath,” “below,” “lower,” “above,” “upper,” “over,” “left,” “right” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As used herein, the terms “approximately,” “substantially,” “substantial” and “about” are used to describe and account for small variations. When used in conduction with an event or circumstance, the terms can refer to instances in which the event of circumstance occurs precisely as well as instances in which the event or circumstance occurs to a close approximation. As used herein with respect to a given value or range, the term “about” generally means within ±10%, ±5%, ±1%, or ±0.5% of the given value or range. Ranges can be expressed herein as from one endpoint to another endpoint or between two endpoints. All ranges disclosed herein are inclusive of the endpoints, unless specified otherwise. The term “substantially coplanar” can refer to two surfaces within micrometers (μm) of lying along a same plane, such as within 10 μm, within 5 μm, within 1 μm, or within 0.5 μm of lying along the same plane. When referring to numerical values or characteristics as “substantially” the same, the term can refer to the values lying within ±10%, ±5%, ±1%, or ±0.5% of an average of the values.

The foregoing outlines features of several embodiments and detailed aspects of the present disclosure. The embodiments described in the present disclosure may be readily used as a basis for designing or modifying other techniques and structures for carrying out the same or similar purposes and/or achieving the same or similar advantages of the embodiments introduced herein. Such equivalent constructions do not depart from the spirit and scope of the present disclosure, and various changes, substitutions, and alterations may be made without departing from the spirit and scope of the present disclosure.

What is claimed is:

1. A semiconductor device, comprising:
a first nitride semiconductor layer;
a second nitride semiconductor layer formed on the first nitride semiconductor layer and having a greater bandgap than that of the first nitride semiconductor layer;
a gate structure disposed on the second nitride semiconductor layer;
a first spacer disposed on the second nitride semiconductor layer; and
a second spacer disposed on the second nitride semiconductor layer and spaced apart from the first spacer by the gate structure,
wherein the bottom of the first spacer has a first width, and the bottom of the second spacer has a second width, and wherein the first width is different from the second width.

2. The semiconductor device of claim 1, further comprising:
a drain electrode disposed relatively adjacent to the first spacer than the second spacer,
wherein the first width is greater than the second width.

3. The semiconductor device of claim 2, further comprising:
a first doped group III-V semiconductor layer connecting to the drain electrode and directly contacting the first nitride semiconductor layer.

4. The semiconductor device of claim 3, further comprising a second doped group III-V semiconductor layer spaced apart from the first doped group III-V semiconductor layer by the second nitride semiconductor layer.

5. The semiconductor device of claim 3, wherein the second nitride semiconductor layer comprises a first surface extending from the first nitride semiconductor layer towards the gate structure, and the first doped group III-V semiconductor layer directly contacts the first surface of the second nitride semiconductor layer.

6. The semiconductor device of claim 3, wherein a distance between the drain electrode and the gate structure is greater than a distance between the first doped group III-V semiconductor layer and the gate structure.

7. The semiconductor device of claim 2, wherein the second spacer comprises a dopant.

8. The semiconductor device of claim 7, wherein the dopant comprises fluorine, phosphorus, boron, carbon, silicon, antimony, germanium, aluminum, indium, or a combination thereof.

9. A semiconductor device, comprising:
a first nitride semiconductor layer having a first surface;
a second nitride semiconductor layer formed on the first surface of the first nitride semiconductor layer and having a greater bandgap than that of the first nitride semiconductor layer; and
a first doped group III-V semiconductor layer and a second doped group III-V semiconductor layer formed on the first surface of the first nitride semiconductor layer and located on two lateral sides of the second nitride semiconductor layer.

10. The semiconductor device of claim 9, wherein the first doped group III-V semiconductor layer and the second doped group III-V semiconductor layer directly contact the first surface of the first nitride semiconductor layer.

11. The semiconductor device of claim 9, wherein the second nitride semiconductor layer has a first surface angled with the first surface of the first nitride semiconductor layer, and the first doped group III-V semiconductor layer directly contacts the first surface of the second nitride semiconductor layer.

12. The semiconductor device of claim 11, wherein the second nitride semiconductor layer has a second surface opposite the first surface, and the second doped group III-V semiconductor layer directly contacts the second surface of the second nitride semiconductor layer.

13. The semiconductor device of claim 9, further comprising:
a gate structure disposed on the second nitride semiconductor layer, wherein a first distance between the first doped group III-V semiconductor layer and the gate structure is different from a second distance between the second doped group III-V semiconductor layer and the gate structure.

14. The semiconductor device of claim 13, further comprising:
a drain electrode connecting to the first doped group III-V semiconductor layer, wherein the first distance between first doped group III-V semiconductor layer and the gate structure is greater than the second distance between the second doped group III-V semiconductor layer and the gate structure.

15. The semiconductor device of claim 13, further comprising:
a drain electrode connecting to the first doped group III-V semiconductor layer, wherein a third distance between the drain electrode and the gate structure is greater than the first distance between the first doped group III-V semiconductor layer and the gate structure.

16. The semiconductor device of claim 9, further comprising:
a first spacer disposed between the gate structure and the first doped group III-V semiconductor layer.

17. A method for fabricating a semiconductor device, comprising:
forming a first nitride semiconductor layer;
forming a second nitride semiconductor layer on a first surface of the first nitride semiconductor layer, the second nitride semiconductor layer having a greater bandgap than that of the first nitride semiconductor layer;
forming a gate structure on the second nitride semiconductor layer;
forming a passivation layer on the second nitride semiconductor layer and the gate structure; and
anisotropically removing a portion of the passivation layer.

18. The method of claim 17, further comprising:
forming a dummy gate structure on the second nitride semiconductor layer;
forming the passivation layer on the dummy gate structure;
forming a dopant into the passivation layer; and
etching the passivation layer to anisotropically remove the portion of the passivation layer and form a first spacer and a second spacer on two lateral sides of the dummy gate structure.

19. The method of claim 18, further comprising:
using the first spacer and the second spacer as a mask to remove portions of the second nitride semiconductor layer exposed from the first spacer and the second spacer and form two recesses over the first nitride semiconductor layer; and
forming a first doped group III-V semiconductor layer and a second doped group III-V semiconductor layer in the two recesses.

20. The method of claim 18, wherein the dopant is implanted from a first direction, and an angle between the first direction and the first surface of the first nitride semiconductor layer is from about 15° to about 90°.
